(19) United States
(12) Patent Application Publication
(10) Pub. No.: US 2019/0237279 A1
(43) Pub. Date: Aug. 1, 2019

(54) CAP STRUCTURE AND KEYSWITCH THEREOF

(71) Applicant: DARFON ELECTRONICS CORP., Taoyuan City (TW)

(72) Inventors: Tsai-Jung Hu, Taoyuan City (TW); Yu-Chih Chang, Taoyuan City (TW)

(21) Appl. No.: 16/248,794

(22) Filed: Jan. 16, 2019

(30) Foreign Application Priority Data
Jan. 29, 2018 (TW) 107103020

(51) Int. Cl. H01H 13/83; H05K 1/18; G06K 9/00

(52) U.S. Cl. CPC H01H 13/83; H05K 1/189; G06K 9/00053; H01R 35/02; H05K 2201/10128; H05K 2201/10151; H05K 2201/10053

(57) ABSTRACT

A cap structure is combined with a lifting mechanism to be movable between a pressed position and a non-pressed position. The cap structure includes a first circuit, a second circuit, a flexible circuit board and a cap having a top surface, a bottom surface and an engaging structure. The engaging structure protrudes from the bottom surface for engaging with the lifting mechanism. The first circuit is laid out on the top surface for connecting to a sensing device or a display device attached on the top surface. The second circuit is laid out on the bottom surface and avoids the engaging structure. The second circuit passes through the cap to be connected to the first circuit. The flexible circuit board is connected to the second circuit for performing signal transmission of the sensing device or the display device via the first and second circuits.

### BACKGROUND OF THE INVENTION

### 1. Field of the Invention

The present invention relates to a cap structure and a keyswitch thereof, and more specifically, to a cap structure having a first circuit laid out on a top surface of a cap and a second circuit laid out on a bottom surface of the cap and making the second circuit avoid an engaging structure on the bottom surface and a keyswitch thereof.

### 2. Description of the Prior Art

A keyboard, which is the most common input device, could be found in variety of electronic apparatuses for users to input characters, symbols, numerals and so on. Furthermore, from consumer electronic products to industrial machine tools, they are all equipped with a keyboard for performing input operations.

In practical application for a keyswitch, functional hardware (e.g. a fingerprint identification chip or an electronic paper) and a flexible circuit board are attached to a cap of the keyswitch respectively for establishing signal transmission of the functional hardware such that the keyswitch could have other application function (e.g. a fingerprint identification function or an image display function).

In the aforesaid design, for preventing the cap from interfering with the flexible circuit board during the cap assembly process, an engaging sheet is additionally attached to the flexible circuit board after the flexible circuit board has been coupled to the functional hardware, and is then connected to the cap and a lifting mechanism of the keyswitch. However, this design causes a time-consuming and strenuous cap assembly process and poor assembly quality, so as to reduce the production quality of the keyboard.

### SUMMARY OF THE INVENTION

The present invention provides a cap structure combined with a lifting mechanism to be movable between a pressed position and a non-pressed position. The cap structure includes a cap, a first circuit, a second circuit, and a flexible circuit board. The cap has a top surface, a bottom surface and an engaging structure. The top surface and the bottom surface are opposite to each other. The engaging structure protrudes from the bottom surface to be engaged with the lifting mechanism. The first circuit is laid out on the top surface for connecting to a sensing device or a display device attached on the top surface. The second circuit is laid out on the bottom surface. The second circuit avoids the engaging structure and passes through the cap to be connected to the first circuit. The flexible circuit board is connected to the second circuit for performing signal transmission of the sensing device or the display device via the first circuit and the second circuit.

The present invention further provides a keyswitch. The keyswitch includes a bottom board, a lifting mechanism, and a cap structure. The lifting mechanism is disposed on the bottom board. The cap structure is combined with the lifting mechanism to be movable between a pressed position and a non-pressed position. The cap structure includes a cap, a first circuit, a second circuit, and a flexible circuit board. The cap has a top surface, a bottom surface and an engaging structure. The top surface and the bottom surface are opposite to each other. The engaging structure protrudes from the bottom surface to be engaged with the lifting mechanism. The first circuit is laid out on the top surface for connecting to a sensing device or a display device attached on the top surface. The second circuit is laid out on the bottom surface. The second circuit avoids the engaging structure and passes through the cap to be connected to the first circuit. The flexible circuit board is connected to the second circuit for performing signal transmission of the sensing device or the display device via the first circuit and the second circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a keyboard according to an embodiment of the present invention.

FIG. 2 is a cross-sectional diagram of a keyswitch in FIG. 1 along a cross-sectional line A-A.

FIG. 3 is an exploded diagram of a cap structure in FIG. 2.

FIG. 4 is an assembly diagram of the cap structure in FIG. 3 from another viewing angle.

FIG. 5 is a cross-sectional diagram of a keyswitch according to another embodiment of the present invention.

### DETAILED DESCRIPTION

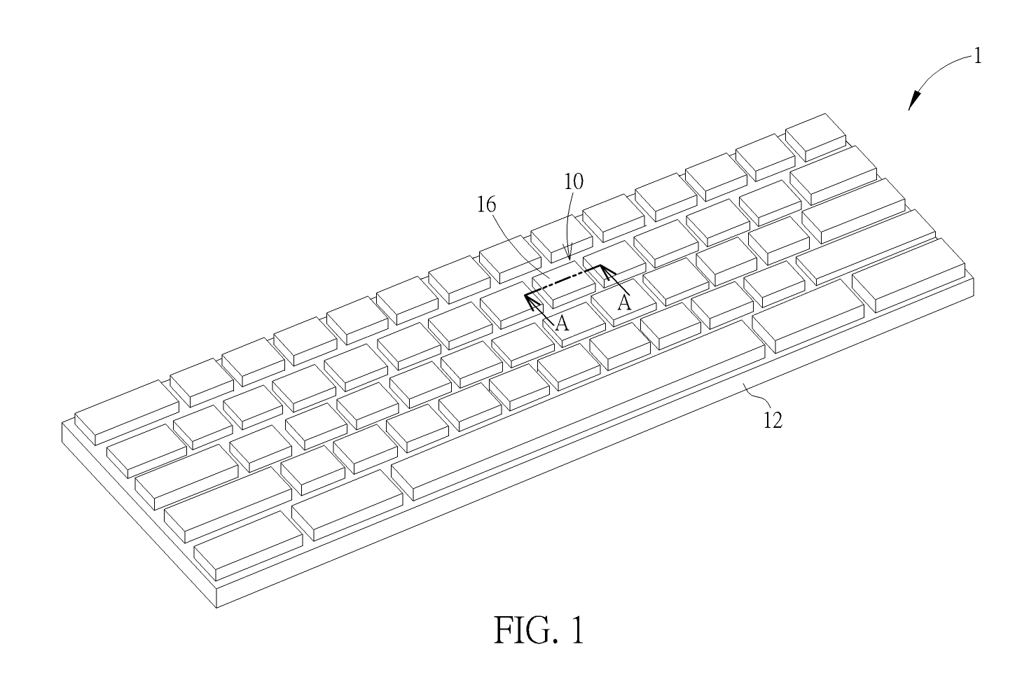

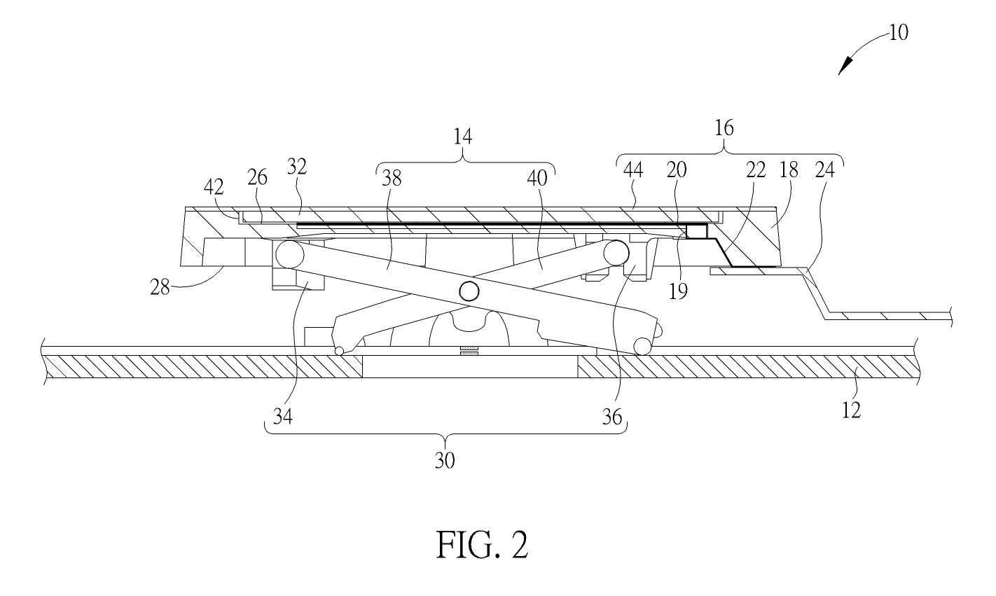

Please refer to FIG. 1 and FIG. 2. FIG. 1 is a diagram of a keyboard 1 according to an embodiment of the present invention. FIG. 2 is a cross-sectional diagram of a keyswitch 10 in FIG. 1 along a cross-sectional line A-A. As shown in FIG. 1 and FIG. 2, the keyboard 1 includes a plurality of keyswitches 10 and a bottom board 12. The plurality of keyswitches 10 is disposed on the bottom board 12 for a user to perform input operations. To be noted, the keyboard 1 could be preferably applied to a portable electronic device with a foldable mechanism composed of an upper cover and a lower casing (e.g. a notebook keyboard or a foldable keyboard).

In the present invention, the cap structural design could be applied to at least one of the plurality of keyswitches 10. More detailed description for only one keyswitch 10 to which the aforesaid cap structural design is applied is provided as follows. As for the related description for other keyswitches 10 adopting the same cap structural design, it could be reasoned by analogy.

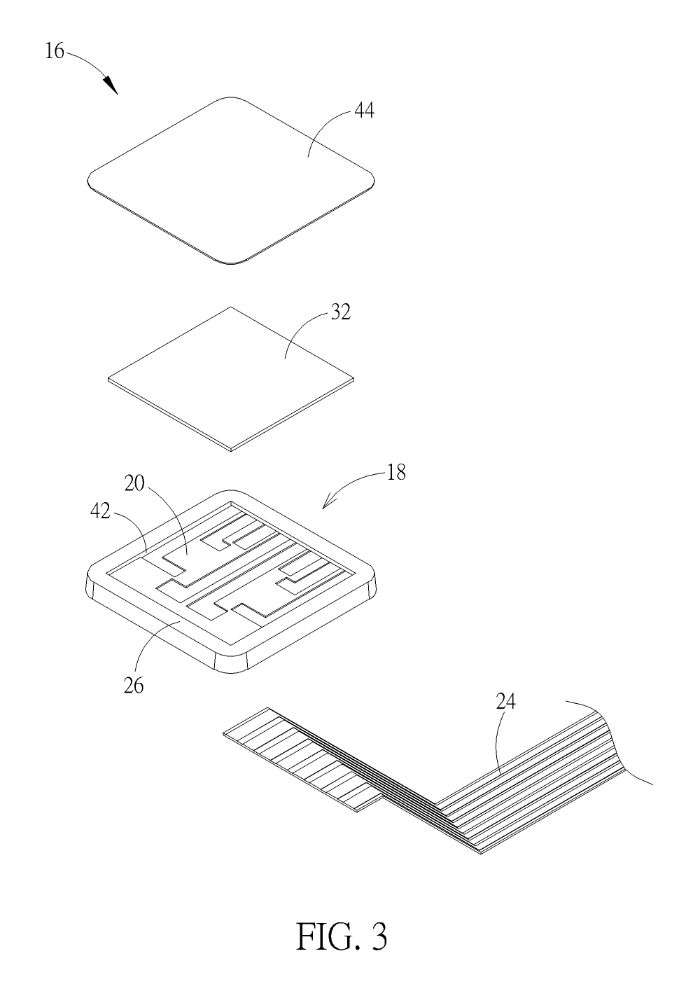

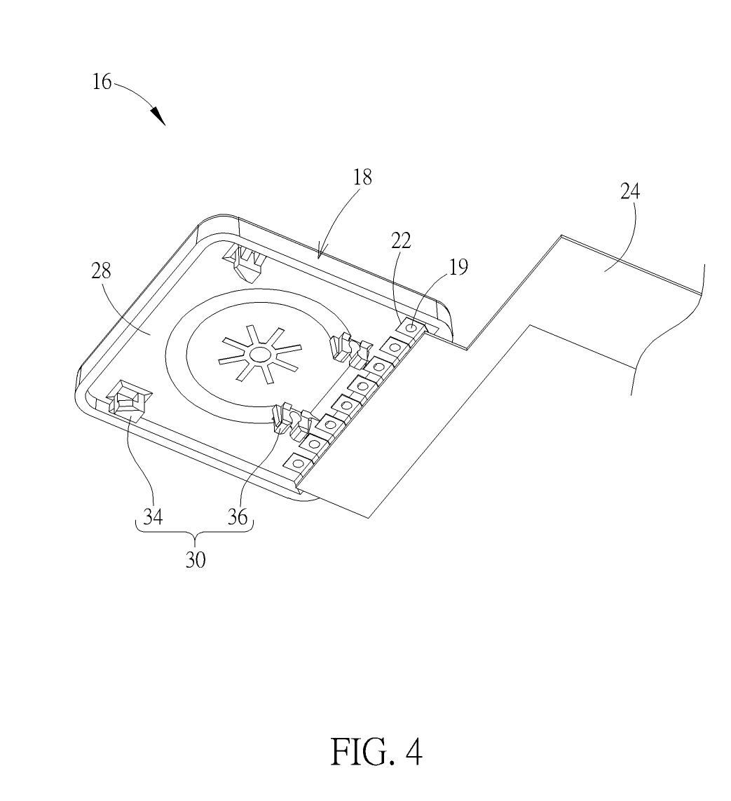

Please refer to FIG. 2, FIG. 3 and FIG. 4. FIG. 3 is an exploded diagram of the cap structure 16 in FIG. 2. FIG. 4 is an assembly diagram of the cap structure 16 in FIG. 3 from another viewing angle. As shown in FIG. 2, FIG. 3, and FIG. 4, the keyswitch 10 includes the bottom board 12, a lifting mechanism 14, and a cap structure 16. The lifting mechanism 14 is disposed on the bottom board 12. The cap structure 16 is combined with the lifting mechanism 14 to be movable between a pressed position and a non-pressed position relative to the bottom board 12. The cap structure 16 includes a cap 18, a first circuit 20, a second circuit 22, and a flexible circuit board 24. The cap 18 has a top surface 26, a bottom surface 28, and an engaging structure 30. The top surface 26 and the bottom surface 28 are opposite to each other. The engaging structure 30 protrudes downward from the bottom surface 28 for engaging with the lifting mechanism 14. The first circuit 20 is laid out on the top surface 26. The second circuit 22 is laid out on the bottom surface 28 and avoids the engaging structure 30. The second circuit 22 passes through the cap 18 to be connected to the first circuit 20. The flexible circuit board 24 is connected to the second circuit 22.

To more specific, the first circuit 20 is connected to the sensing device 32 attached to the top surface 26. Accordingly, electrical signal transmission between the flexible circuit board 24 and the sensing device 32 can be established by the first circuit 20 and the second circuit 22. The sensing device 32 could preferably be a fingerprint identification chip (but not limited thereto, meaning that the sensing device 32 could be other type of sensing device, such as a touch sensing chip) such that the cap structure 16 could have a fingerprint identification function. Furthermore, the present invention could also adopt other functional design. For example, in another embodiment, the first circuit 20 could be connected to a display device (e.g. an OLED layer or an electronic paper) attached to top surface 26 such that the cap structure 16 could have an image display function. In addition, in this embodiment, the cap 18 could further have at least one through hole 19 (one shown in FIG. 2, but not limited thereto). The through hole 19 passes through the top surface 26 to the bottom surface 28. The first circuit 20 and the second circuit 22 could preferably be formed by an LDS (Laser Direct Structuring) process or an electronic printing process such that the second circuit 22 could be connected to the first circuit 20 via the through hole 19. As for the related description for the aforesaid circuit forming process, it is commonly seen in the prior art and omitted herein.

As shown in FIG. 2, in this embodiment, the engaging structure 30 could include a slide slot member 34 and a pivot slot member 36. The slide slot member 34 and the pivot slot member 36 are spaced from each other on the bottom surface 28. The lifting mechanism 14 could include a first support member 38 and a second support member 40. The first support member 38 is movably connected to the bottom board 12 and slidably connected to the slide slot member 34. The second support member 40 is movably connected to the bottom board 12 and pivotably connected to the pivot slot member 36. The first support member 38 pivotably intersects with the second support member 40 to form a scissor support mechanism on the bottom board 12, so as to make the cap 18 movable between a pressed position and a non-pressed position relative to the bottom board 12 for a user to press.

In practical application, as shown in FIG. 3, a recessed structure 42 is formed on the bottom surface 26 for containing the sensing device 32 and positioning the sensing device 32 on the top surface 26. Moreover, the cap structure 16 could further include a protection sheet 44. The protection sheet 44 is disposed on the top surface 26 for covering the sensing device 32, so as to generate the surface decoration and protection effect.

In summary, compared with the prior art involving additionally attaching the engaging sheet to the cap and the flexible circuit board, the present invention adopts the design in which the first circuit and the second circuit are laid out on the top surface and the bottom surface respectively and the second circuit avoids the engaging structure on the bottom surface of the cap, so as to establish electrical signal transmission between the flexible circuit board and the sensing device (or the display device) via the first circuit and the second circuit. In such a manner, since there is no need to additionally dispose an engaging sheet on the cap structure of the present invention, the present invention can efficiently solve the prior art problem that the cap assembly process is time-consuming and strenuous and the assembly quality of the keyswitch is poor due to additional attachment of the engaging sheet, so as to improve the production quality of the keyboard. Furthermore, via the additional function provided by the sensing device (or the display device) attached to the first circuit, the functionality and practicality of the keyswitch can be greatly improved.

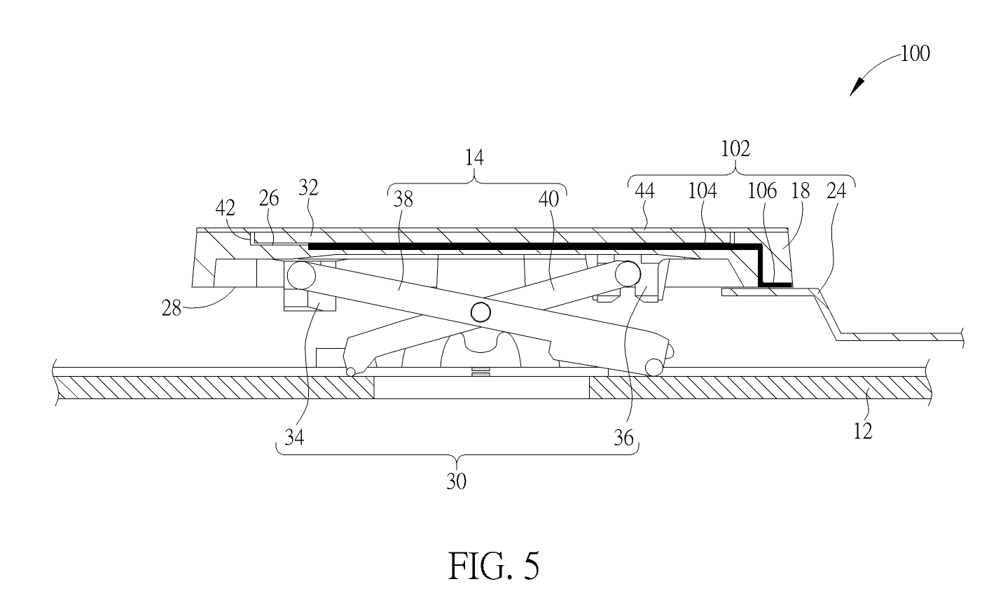

It should be mentioned that the design of forming the first circuit and the second circuit on the cap is not limited to the aforesaid embodiment. For example, please refer to FIG. 5, which is a cross-sectional diagram of a keyswitch 100 according to another embodiment of the present invention. Components both mentioned in this embodiment and the aforesaid embodiment represent components with similar functions or structures. As shown in FIG. 5, the keyswitch 100 includes the bottom board 12, the lifting mechanism 14, and the cap structure 102. The cap structure 102 is combined with the lifting mechanism 14 to be movable between the pressed position and the non-pressed position relative to the bottom board 12. The cap structure 102 includes the cap 18, the flexible circuit board 24, the protection sheet 44, a first circuit 104, and a second circuit 106. In this embodiment, the first circuit 104 and the second circuit 106 form a lead frame structure cooperatively. The lead frame structure could preferably be formed integrally with the cap 18 by an insert molding process such that electrical signal transmission between the flexible circuit board 24 and the sensing device 32 (or the display device) can be established via the first circuit 104 and the second circuit 106. As for other related description for the keyswitch 100, it could be reasoned by analogy according to the aforesaid embodiment and omitted herein.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A cap structure combined with a lifting mechanism to be movable between a pressed position and a non-pressed position, the cap structure comprising:
a cap having a top surface, a bottom surface and an engaging structure, the top surface and the bottom surface being opposite to each other, the engaging structure protruding from the bottom surface to be engaged with the lifting mechanism;
a first circuit laid out on the top surface for connecting to a sensing device or a display device attached on the top surface;
a second circuit laid out on the bottom surface, the second circuit avoiding the engaging structure and passing through the cap to be connected to the first circuit; and
a flexible circuit board connected to the second circuit for performing signal transmission of the sensing device or the display device via the first circuit and the second circuit.

2. The cap structure of claim 1, wherein the cap further has at least one through hole formed from the top surface to the bottom surface, and the first circuit and the second circuit is formed by an LDS (Laser Direct Structuring) process or an electronic printing process for connecting the second circuit to the first circuit via the at least one through hole.

3. The cap structure of claim 1, wherein the first circuit and the second circuit form a lead frame structure cooperatively, and the lead frame structure is formed integrally with the cap by an insert molding process.

4. The cap structure of claim 1, wherein a recessed structure is formed on the top surface for containing the sensing device or the display device.

5. The cap structure of claim 1 further comprising:
a protection sheet disposed on the top surface for covering the sensing device or the display device.

6. The cap structure of claim 1, wherein the engaging structure comprises a slide slot member and a pivot slot member, the slide slot member and the pivot slot member are spaced from each other on the bottom surface, the lifting mechanism is a scissor support mechanism, and the lifting mechanism is slidably connected to the slide slot member and pivotably connected to the pivot slot member to make the cap movable between the pressed position and the non-pressed position.

7. The cap structure of claim 1, wherein the sensing device is a fingerprint identification chip, and the display device is an OLED (Organic Light Emitting Diode) layer or an electronic paper.

8. A keyswitch comprising:
a bottom board;
a lifting mechanism disposed on the bottom board; and
a cap structure combined with the lifting mechanism to be movable between a pressed position and a non-pressed position, the cap structure comprising:
a cap having a top surface, a bottom surface and an engaging structure, the top surface and the bottom surface being opposite to each other, the engaging structure protruding from the bottom surface to be engaged with the lifting mechanism;
a first circuit laid out on the top surface for connecting to a sensing device or a display device attached on the top surface;
a second circuit laid out on the bottom surface, the second circuit avoiding the engaging structure and passing through the cap to be connected to the first circuit; and
a flexible circuit board connected to the second circuit for performing signal transmission of the sensing device or the display device via the first circuit and the second circuit.

9. The keyswitch of claim 8, wherein the cap further has at least one through hole formed from the top surface to the bottom surface, and the first circuit and the second circuit is formed by an LDS (Laser Direct Structuring) process or an electronic printing process for connecting the second circuit to the first circuit via the at least one through hole.

10. The keyswitch of claim 8, wherein the first circuit and the second circuit form a lead frame structure cooperatively, and the lead frame structure is formed integrally with the cap by an insert molding process.

11. The keyswitch of claim 8, wherein a recessed structure is formed on the top surface for containing the sensing device or the display device.

12. The keyswitch of claim 8, wherein the cap structure further comprises:
a protection sheet disposed on the top surface for covering the sensing device or the display device.

13. The keyswitch of claim 8, wherein the engaging structure comprises a slide slot member and a pivot slot member, the slide slot member and the pivot slot member are spaced from each other on the bottom surface, the lifting mechanism comprises a first support member and a second support member, the first support member is movably connected to the bottom board and slidably connected to the slide slot member, the second support member is movably connected to the bottom board and pivotably connected to the pivot slot member, and the first support member and the second support member pivotably intersect with each other to make the cap movable between the pressed position and the non-pressed position.

14. The keyswitch of claim 8, wherein the sensing device is a fingerprint identification chip, and the display device is an OLED layer or an electronic paper.
